(19) United States
(12) Patent Application Publication
(10) Pub. No.: US 2002/0155376 A1
(43) Pub. Date: Oct. 24, 2002

(54) Positive resist composition

(76) Inventors: Kazuhiko Hashimoto, Tsukuba-shi (JP); Yasunori Uetani, Osaka (JP); Yoshiko Miya, Kyoto-shi (JP)

Correspondence Address: BIRCH STEWART KOLASCH & BIRCH, PO BOX 747, FALLS CHURCH, VA, 22040-0747, US

(21) Appl. No.: 09/946,556

(22) Filed: Sep. 6, 2001

(30) Foreign Application Priority Data
Sep. 11, 2000 (JP) 2000-274517
Nov. 17, 2000 (JP) 2000-350775

(51) Int. Cl. G03F 7/039

(52) U.S. Cl. 430/270.1; 430/945

(57) ABSTRACT

A positive resist composition comprising a binder resin and a radiation-sensitive compound, wherein the binder resin contains a polymerization unit of the following formula (I) and a polymerization unit of the following formula (II) and becomes alkali-soluble by the radiation-sensitive compound after irradiation with radioactive ray:

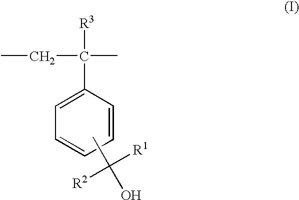

wherein, R¹ and R² each independently represent a fluoroalkyl group having 1 to 12 carbon atoms and carrying at least one fluorine atom, and R³ represents a hydrogen atom, halogen atom, cyano group, alkyl group having 1 to 3 carbon atoms or a fluoroalkyl group having 1 to 3 carbon atoms and carrying at least one fluorine atom,

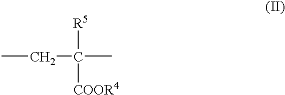

wherein, R⁴ represents a group which is cleaved by an acid, and R⁵ represents a hydrogen atom, halogen atom, cyano group, alkyl group having 1 to 3 carbon atoms or a fluoroalkyl group having 1 to 3 carbon atoms and carrying at least one fluorine atom.

### FIELD OF THE INVENTION

The present invention relates to a positive resist composition comprising a binder resin and a radiation-sensitive compound.

### BACKGROUND OF THE INVENTION

In fine processing of semiconductors, a lithography process using a resist composition is usually adopted. As an exposure light source for lithography, F₂ excimer laser having a wavelength of 157 nm is regarded as hopeful as an exposure light source of next generation.

However, resins used in resists to be exposed to KrF excimer laser having a wavelength of 248 nm and ArF excimer laser having a wavelength of 193 nm have problems that abilities such as profile, contrast, sensitivity and the like are poor and resolution in exposure is not at sufficiently satisfactory level since the resins do not manifest sufficient transparency against lights having a wavelength of 170 nm or less, for example, F₂ excimer laser having a wavelength of 157 nm.

For example, Proc. SPIE vol. 1672 500 (1992) and DE patent No. 4207261 disclose a resist composition using a resin containing a polymerization of the following formula. However, the resulting resist does not manifest sufficiently satisfactory resolution in exposure.

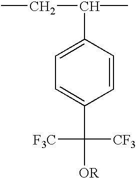

Further, resist compositions using a resin containing a polymerization unit having a nitrile group are disclosed in J. Photopolym. Sci. Technol., Vol. 13, No. 3, 459, (2000), Abstract of 57th Autumn Meeting of JSAP (Japan Society of Applied Physics)in 1996, p. 474, Proc. SPIE-Int. Soc. Opt. Eng. (1998) 3333, JP-A Nos. 06-16730, 07-234511, 10-301285, 11-258809 and 11-352694.

Furthermore, JP-A No. 9-73173 discloses a resist composition using a resin having 2-methyl-2-adamantyl methacrylate and acrylonitrile as polymerization units.

However, resists obtained from these compositions using a resin containing a polymerization unit having a nitrile group have a problem that transparency against F₂ excimer laser having a wavelength of 157 nm is not sufficient.

### SUMMARY OF THE INVENTION

An object of the present invention is to provide a positive resist composition excellent in resolution in exposure and transparency against light having a wavelength of 170 nm or less.

The present inventors have intensively studied to find a positive resist composition not having the above-described problems, and resultantly found that a resist composition comprising a resin having a polymerization unit derived from a hydroxyfluoroalkylated styrene derivative and a polymerization unit derived from an acrylate derivative is excellent in resolution in exposure and transmission against light having a wavelength of 170 nm or less, and have completed the present invention.

Namely, the present invention provides a positive resist composition comprising a binder resin and a radiation-sensitive compound, wherein the binder resin contains a polymerization unit of the following formula (I) and a polymerization unit of the following formula (II) and becomes alkali-soluble by the radiation-sensitive compound after irradiation with radioactive ray:

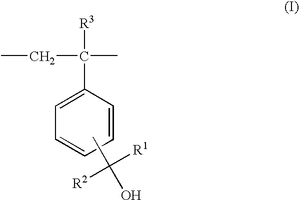

wherein, R¹ and R² each independently represent a fluoroalkyl group having 1 to 12 carbon atoms and carrying at least one fluorine atom, and R³represents a hydrogen atom, halogen atom, cyano group, alkyl group having 1 to 3 carbon atoms or a fluoroalkyl group having 1 to 3 carbon atoms and carrying at least one fluorine atom,

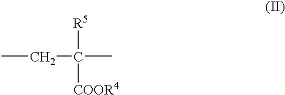

wherein, R⁴ represents a group which is cleaved by an acid, and R⁵ represents a hydrogen atom, halogen atom, cyano group, alkyl group having 1 to 3 carbon atoms or a fluoroalkyl group having 1 to 3 carbon atoms and carrying at least one fluorine atom.

### DETAILED DESCRIPTION OF THE PREFERRED EMBODIMENTS

The present invention will be illustrated in detail below.

In the present invention, a resin containing a polymerization unit of the above-described formula (I) and a polymerization unit of the above-described formula (II) is used as the binder resin.

The polymerization unit of the formula (I) is preferably a polymerization unit of the following formula (III).

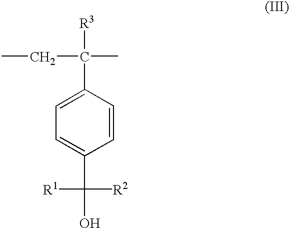

In the formulae (I) and (III), R¹ and R² each independently represent a fluoroalkyl group having 1 to 12 carbon atoms and carrying at least one fluorine atom. Examples of R¹ and R² include a fluoromethyl group, difluoromethyl group, trifluoromethyl group, pentafluoroethyl group, 1-trifluoromethyl-2,2,2-trifluoroethyl group and the like.

The fluoroalkyl group represented by R¹ and R² may be branched when it contains three or more carbon atoms. Among others, it is preferable that both of R¹ and R² are a trifluoromethyl group.

R³ represents a hydrogen atom, a halogen atom such as a fluorine atom, chlorine atom, bromine atom and the like, a cyano group, an alkyl group having 1 to 3 carbon atoms such as a methyl group, ethyl group, n-propyl group and the like, or a fluoroalkyl group having 1 to 3 carbon atoms and carrying at least one fluorine atom such as a trifluoromethyl group and the like.

In the formula (II), R⁴ is an acid-labile group which has an ability to suppress dissolution into alkali developer but is instable against an acid.

Examples of the acid-labile group include groups in which a quaternary carbon is connected to an oxygen atom such as a tert-butyl group, tert-butoxycarbonyl group or tert-butoxycarbonylmethyl group and the like; acetal type groups such as a tetrahydro-2-pyranyl group, tetrahydro-2-furyl group, 1-ethoxyethyl group, 1-(2-methylpropoxy)ethyl group, 1-(2-methoxyethoxy)ethyl group, 1-(2-acetoxyethoxy)ethyl group, 1-[2-(1-adamentyloxy)ethoxy]ethyl group or 1-[2-(1-adamantanecarbonyloxy)ethoxy]ethyl group and the like; groups of non-aromatic cyclic compounds such as a 3-oxocyclohexyl group, 4-methyltetrahydro-2-pyron-4-yl group (derived from mevalonic lactone), 1-adamantyl-1-alkylalkyl group or 2-alkyl-2-adamantyl group and the like; and other groups. Of then, a 2-alkyl-2-adamantyl group is preferable.

R⁵ represents a hydrogen atom, a halogen atom such as a fluorine atom, chlorine atom, bromine atom and the like, a cyano group, an alkyl group having 1 to 3 carbon atoms such as a methyl group, ethyl group, n-propyl group and the like, or a fluoroalkyl group having 1 to 3 carbon atoms and carrying at least one fluorine atom such as a trifluoromethyl group and the like.

The binder resin is obtained, for example, by polymerizing a monomer of the following formula (VI) with an acrylate monomer CH₂═CR⁵COOR⁴ (wherein, R⁴ and R⁵ are as defined in the formula (II)). A compound of the formula (VI) can be produced by a method, for example, described in J. Macromol. Sci. Chem., A21, 1181 (1984).

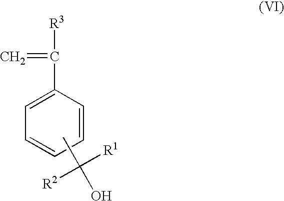

R¹, R² and R³ are as defined in the formula (I).

A compound of the formula (VI) in which both of R¹ and R² are a trifluoromethyl group is preferable from the standpoint of industrial production since it can be derived from hexafluoroacetone available easily from market.

R⁴ and R⁵ in the acrylate monomer are as defined in the formula (II).

As the acrylate monomer, 2-alkyl-2-adamantyl acrylate is preferable. 2-alkyl-2-adamantyl acrylate is represented by the following formula (VII), and can form a polymerization unit of the following formula (VIIa)

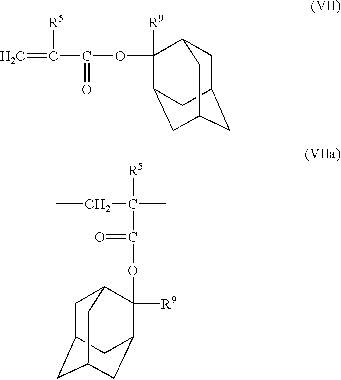

In the formulae (VII) and (VIIa), R⁹ represents an alkyl group, and this alkyl group preferably has 1 to 8 carbon atoms, and usually is liner advantageously, however, it may also branched in the case of three or more carbon atoms.

Specific examples of R⁹ include a methyl group, ethyl group, propyl group, isopropyl group, butyl group and the like.

The binder resin used in the present invention is alkali-insoluble itself, however, causes chemical change to become alkali-soluble by the action of a radiation-sensitive compound after irradiation with radioactive ray.

Parts irradiated with radioactive ray of a resist film containing this binder resin are removed by an alkali (hereinafter, sometimes referred to as alkali development) to give a positive resist since the parts have become alkali-soluble. Namely, in a positive resist of chemical amplification type, an acid generated from a radiation-sensitive compound at part irradiated with radioactive ray is diffused by the subsequent thermal treatment (post exposure bake), and causes cleavage of a protective group of the resin, rendering the part irradiated with radioactive ray alkali-soluble.

For example, a resin having a polymerization unit of 2-alkyl-2-adamantyl methacrylate of the formula (VIIa) is preferable as a positive resist since a 2-alkyl-2-adamantyl group is cleaved by the action of an acid generated from a radiation-sensitive compound and becomes alkali-soluble.

Further, in the binder resin of the present invention, a resin containing a polymerization unit derived from acrylonitrile represented by the following formula (IV) in addition to polymerization units of the formula (I) and formula (II) can also be used.

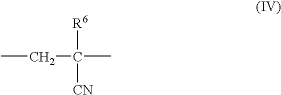

In the formula, R⁶ represents a hydrogen atom, halogen atom, cyano group, alkyl group having 1 to 3 carbon atoms or a fluoroalkyl group having 1 to 3 carbon atoms and carrying at least one fluorine atom.

As the alkyl group having 1 to 3 carbon atoms, for example, a methyl group, ethyl group, propyl group, isopropyl group and the like are listed, and a methyl group is preferable from the standpoint of easiness of polymerization.

Examples of the fluoroalkyl group having 1 to 3 carbon atoms include a fluoromethyl group, difluoromethyl group, trifluoromethyl group, pentafluoroethyl group, 1-trifluoromethyl-2,2,2-trifluoroethyl group and the like.

Specifically, as the polymerization unit of the formula (IV), polymerization units derived from acrylonitrile and methacrylonitrile, and the like are listed.

Further, in the binder resin of the present invention, a resin containing a polymerization unit derived from vinylphenol represented by the following formula (V) in addition to polymerization units of the formula (I) and formula (II) can also be used.

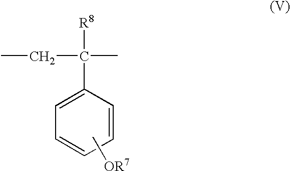

In the formula, R⁷ represents a group which is cleaved by the action of an acid as for R⁴, or a hydrogen atom, and R⁸represents a hydrogen atom, halogen atom, cyano group, alkyl group having 1 to 3 carbon atoms or a fluoroalkyl group having 1 to 3 carbon atoms and carrying at least one fluorine atom.

As the alkyl group having 1 to 3 carbon atoms, for example, a methyl group, ethyl group, propyl group, isopropyl group and the like listed.

Examples of the fluoroalkyl group having 1 to 3 carbon atoms include a fluoromethyl group, difluoromethyl group, trifluoromethyl group, pentafluoroethyl group, 1-trifluoromethyl-2,2,2-trifluoroethyl group and the like.

Furthermore, in the binder resin of the present invention, a resin containing polymerization units of the formula (IV) and formula (V) in addition to polymerization units of the formula (I) and formula (II) can also be used.

In the binder resin used in the present invention, a polymerization unit of the formula (I) functions as an alkali-soluble part, however, other alkali-soluble polymerization units may also be added, and as this polymerization unit, for example, a polymerization unit having aphenol skeleton, a polymerization unit having a (meth) acrylate skeleton and having an alicyclic ring and carboxyl group at the alcohol side of the ester, a polymerization unit of an unsaturated carboxylic acid, a polymerization unit having —C(CF₃)₂OH other than those represented by the formula (I), and the like are listed.

Specifically, a vinylphenol unit, isopropenylphenol unit, (meth)acrylic acid unit, polymerization unit represented by —CH₂—C(CF₃)OH— described in J. photopolym. Sci. Technol. Vol 13, p451, and polymerization unit derived from 3-(5-bicyclo[2.2.1]hepten-2-yl)-1,1,1-trifluoro-2-(trifluoromethyl)-2-propanol described in the same literature, and the like are listed.

Of the alkali-soluble parts as described above, those having part protected by a group which is cleaved by the action of an acid may also be used.

As the group protecting the alkali-soluble part, the same groups as for R⁴ are listed.

Further, analkali-insoluble polymerization unit may also be present only providing the whole binder resin becomes alkali-soluble due to chemical change by the action of a radiation-sensitive compound after irradiation with radioactive ray. The alkali-insoluble polymerization unit in a binder resin does not cause itself chemical change by the action of a radiation-sensitive compound after irradiation with radioactive ray, however, is not particularly restricted providing it does not deteriorate alkali-solubility of the whole binder resin after irradiation with radioactive ray.

Specific examples thereof include a polymerization unit in which part of hydroxyl groups of a vinylphenol unit or isopropenylphenol unit is alkyl etherified, a polymerization unit obtained by an alicyclic ester of (meth)acrylic acid, a polymerization unit in which partial or all hydrogen atoms of an alkyl ester of a polymerization unit, (meth)acrylic acid of a cycloolefin such as 2-norbornene and the like or derivative thereof are substituted with fluorine atoms, a polymerization unit in which partial or all hydrogen atoms of an alkene are substituted with fluorine atoms, and the like.

In the present invention, a polymerization unit of the formula (IV), a polymerization unit of the formula (V), a polymerization unit of the above-mentioned alkali-soluble group, a polymerization unit in which part of the above-mentioned alkali-soluble part is protected by a group which is cleaved by the action of an acid, and a polymerization unit which is insoluble in an alkali can be allowed to present in a binder resin in addition to a polymerization unit of the formula (I) and a polymerization unit of the formula (II).

The binder resin usually contains a polymerizable unsaturated compound having a polymerization unit of the formula (I) and a polymerization unit of the formula (II), for example, and further, if necessary, can be produced by copolymerization with a polymerizable unsaturated compound which derives a polymerization unit of the formula (IV), a polymerizable unsaturated compound which derives a polymerization unit of the formula (V), an alkali-soluble group, a polymerization unit in which part of the alkali-soluble part is protected by a group which is cleaved by the action of an acid, and a polymerizable unsaturated compound which derives a polymerization unit containing an alkali-insoluble group and the like. The copolymerization reaction can be conducted according to an ordinary method, and for example, a method in which monomers are dissolved in a suitable solvent, and polymerization is initiated in the presence of a polymerization initiator, to start the reaction, and other methods are listed.

By incorporation of polymerization units of the formula (I) and formula (II) into a binder resin, the binder resin gets excellent transmission against lights having a wavelength of 170 nm or less, for example, F₂ excimer laser having a wavelength of 157 nm.

The proportion of polymerization units of the formula (I) and formula (II) is preferably controlled so that a binder resin itself insoluble or poorly soluble in alkali developer becomes alkali-soluble by the action of a radiation-sensitive compound after irradiation with radioactive ray.

Depending on the kind and type of a resist, the proportion of a polymerization unit of the formula (I) is preferably from 5 to 95 mol %, more preferably from 50 to 90 mol %, further preferably from 60 to 85 mol % based on the whole binder resin, in general.

The proportion of a polymerization unit of the formula (II) is preferably from 5 to 95 mol %, more preferably from 10 to 50 mol %, further preferably from 15 to 40 mol % based on the whole binder resin. Further, a polymerization unit of the formula (IV), a polymerization unit of the formula (V), other alkali-soluble polymerization unit than that of the formula (I), and an alkali-insoluble polymerization unit may also be contained, and the proportion of these polymerization unit is preferably from 0 to 50 mol %, more preferably from 0 to 40 mol % in total based on the whole binder resin.

As the binder resin in which polymerization units of the formula (I) and formula (II) are incorporated and which causes chemical change to become alkali-soluble by the action of a radiation-sensitive compound after irradiation with radioactive ray, the following compounds are listed specifically.

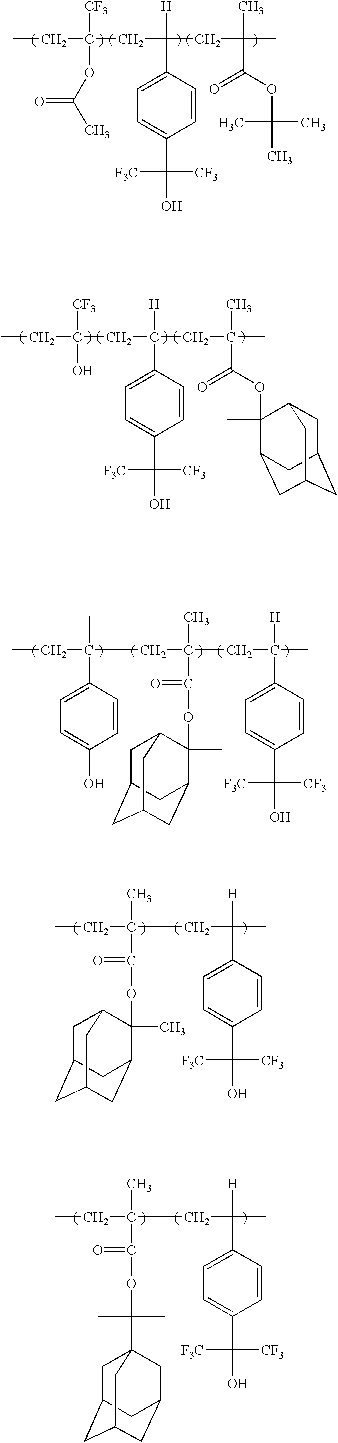

The positive resist of the present invention comprises the above-mentioned resin which can become alkali-soluble, as a binder resin, and a radiation-sensitive compound which is decomposed by the action of radioactive ray.

The binder resin has a group which is cleaved by the action of an acid, and is insoluble or poorly soluble itself in an alkali, however, becomes alkali-soluble after cleavage of the group which is cleaved by the action of an acid.

As the radiation-sensitive compound, an acid generator which generates an acid by the action of radioactive ray is used.

As the radiation-sensitive compound, for example, onium salts, halogenated alkyltriazine-based compounds, disulfone-based compounds, compounds having a diazomethanesulfonyl skeleton, sulfonate-based compounds, and the like are listed.

Specific examples of the onium salt include

diphenyliodonium trifluoromethanesulfonate,

4-methoxyphenylphenyliodonium hexafluoroantimonate,

4-methoxyphenylphenyliodonium trifluoromethanesulfonate,

bis(4-tert-butylphenyl)iodonium tetrafluoroborate,

bis(4-tert-butylphenyl)iodonium hexafluorophosphate,

bis(4-tert-butylphenyl)iodonium hexafluoroantimonate,

bis(4-tert-butylphenyl)iodonium trifluoromethanesulfonate,

triphenylsulfonium hexafluorophosphate,

triphenylsulfonium hexafluoroantimonate,

triphenylsulfonium trifluoromethanesulfonate,

4-methoxyphenyldiphenylsulfonium hexafluoroantimonate,

4-methoxyphenyldiphenylsulfonium trifluoromethanesulfonate,

p-tolyldiphenylsulfonium trifluoromethanesulfonate,

2,4,6-trimethylphenyldiphenylsulfonium trifluoromethanesulfonate,

4-tert-butylphenyldiphenylsulfonium trifluoromethanesulfonate,

4-phenylthiophenyldiphenylsulfonium hexafluorophosphate,

4-phenylthiophenyldiphenylsulfonium hexafluoroantimonate,

1-(2-naphthoylmethyl)thioranium hexafluoroantimonate,

1-(2-naphthoylmethyl)thioranium trifluoromethanesulfonate,

4-hydroxy-1-naphthyldimethylsulfonium hexafluoroantimonate,

4-hydroxy-1-naphthyldimethyluslfonium trifluoromethanesulfonate, and the like.

Examples of the halogenated alkyltriazine compound include

2-methyl-4,6-bis(trichloromethyl)-1,3,5-triazine,

2,4,6-tris(trichloromethyl)-1,3,5-triazine,

2-phenyl-4,6-bis(trichloromethyl)-1,3,5-triazine,

2-(4-chlorophenyl)-4,6-bis(trichloromethyl)-1,3,5-triazine,

2-(4-methoxyphenyl)-4,6-bis(trichloromethyl)-1,3,5-triazine,

2-(4-methoxy-1-naphthyl)-4,6-bis(trichloromethyl)-1,3,5-triazine,

2-(benzo[d][1,3]dioxolan-5-yl)-4,6-bis(trichloromethyl)-1,3,5-triazine,

2-(4-methoxystyryl)-4,6-bis(trichloromethyl)-1,3,5-triazine,

2-(3,4,5-trimethoxystyryl)-4,6-bis(trichloromethyl)-1,3,5-triazine,

2-(3,4-dimethoxystyryl)-4,6-bis(trichloromethyl)-1,3,5-triazine,

2-(2,4-dimethoxystyryl)-4,6-bis(trichloromethyl)-1,3,5-triazine,

2-(2-methoxystyryl)-4,6-bis(trichloromethyl)-1,3,5-triazine,

2-(4-butoxystyryl)-4,6-bis(trichloromethyl)-1,3,5-triazine,

2-(4-pentyloxystyryl)-4,6-bis(trichloromethyl)-1,3,5-triazine, and the like.

As the disulfone-based compound, for example, diphenyldisulfone, di-p-tolyldisulfone, phenyl p-tolyldisulfone, phenyl p-methoxyphenyldisulfone and the like are listed.

Examples of the compound having a diazomethanesulfonyl skeleton include

bis(phenylsulfonyl)diazomethane,

bis(4-chlorophenylsulfonyl)diazomethane,

bis(p-tolylsulfonyl)diazomethane,

bis(4-tert-butylphenylsulfonyl)diazomethane,

bis(2,4-xylylsulfonyl)diazomethane,

bis(cyclohexylsulfonyl)diazomethane,

(benzoyl)(phenylsulfonyl)diazomethane, and the like.

Examples of the sulfonate-based compound include

1-benzoyl-1-phenylmethyl p-toluenesulfonate(trivially, benzoin tosylate),

2-benzoyl-2-hydroxy-2-phenylethyl p-toluenesulfonate (trivially, α-methylolbenzoin tosylate),

1,2,3-benzenetolyl trismethanesulfonate,

2,6-dinitrobenzyl p-toluenesulfonate,

2-nitrobenzyl p-toluenesulfonate,

4-nitrobenzyl p-toluenesulfonate,

N-(phenylsulfonyloxy)succineimide,

N-(p-tolylsulfonyloxy)succineimide,

N-(trifluoromethylsulfonyloxy)succineimide,

N-(isopropylsulfonyloxy)succineimide,

N-(n-butylsulfonyloxy)succineimide,

N-(n-hexylsulfonyloxy)succineimide,

N-(10-camphorsulfonyloxy)succineimide,

N-(trifluoromethylsulfonyloxy)phthalimide,

N-(trifluoromethylsulfonyloxy)-5-norbornene-2,3-dicarboxyimide,

N-(trifluoromethylsulfonyloxy)naphthalimide,

N-(10-camphorsulfonyloxy)naphthalimide, and the like.

In the positive resist composition of the present invention, it is preferable to add a basic compound, particularly, a basic nitrogen-containing organic compound such as amines and the like, as a quencher.

As the specific example of the basic compound, compounds of the following formulae are listed.

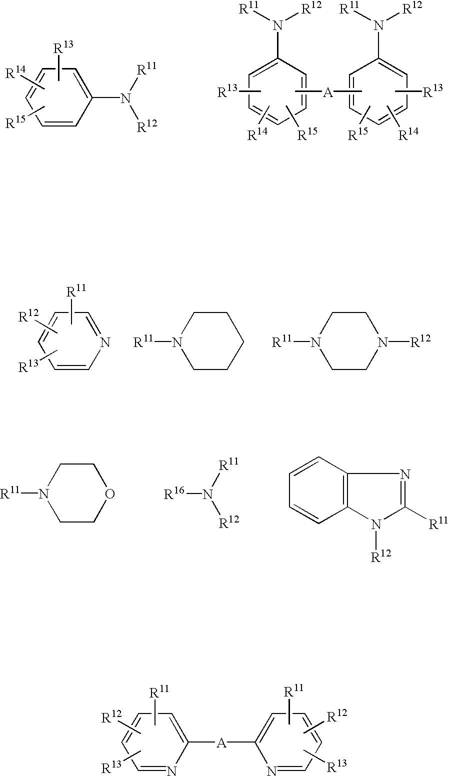

In the formulae, R¹¹ and R¹² each independently represent a hydrogen atom, alkyl group optionally substituted with a hydroxyl group, cycloalkyl group or aryl group, R¹³, R¹⁴ and R¹⁵ each independently represent a hydrogen atom, alkyl group optionally substituted with a hydroxyl group, cycloalkyl group, aryl group or alkoxy group, R¹⁶ represents an alkyl group optionally substituted with a hydroxyl group, or cycloalkyl group, and A represents an alkylene group, carbonyl group or imino group.

It is preferable that the alkyl group represented by R¹¹ to R¹⁶ and the alkoxy group represented by R¹¹ to R¹⁵ have 1 to 6 carbon atoms, the cycloalkyl group represented by R¹¹ to R¹⁶ have 5 to 10 carbon atoms, and the aryl group represented by R¹¹ to R¹⁵ have 6 to 10 carbon atoms.

The alkylene group represented by A preferably has 1 to 6 carbon atoms, and may be linear or branched.

Further, in the positive resist composition of the instant application, a hindered amine compound having a piperidine skeleton may be added as a quencher. As this hindered amine compound, compounds disclosed in JP-A No. 11-52575, and the like are listed.

The positive resist composition of the present invention contains a binder component in an amount of preferably from 60 to 99.9 wt %, more preferably from 80 to 99.9 wt %, and a radiation-sensitive compound in an amount of preferably from 0.1 to 40 wt %, more preferably from 0.1 to 20 wt %, based on the amount of all solid components.

When a radiation-sensitive compound is an acid generating agent and a basic compound is used as a quencher as in the instant application, the basic compound is preferably contained in an amount of about 0.01 to 1 wt % based on the weight of all solid components of the resist composition likewise.

Further, the resist composition may contain, if necessary, various additives such as a sensitizer, other resins, surfactant, stabilizer, dye and the like, in small amount which does not destruct the object of the present invention.

The resist composition of the present invention usually gives resist liquid when the above-mentioned components are dissolved in a solvent, and applied on a substrate such as a silicon wafer and the like according to an ordinary method such as spin coating and the like.

The solvent herein used may advantageously be that which dissolves component, has suitable drying speed, and provides a uniform and smooth film after evaporation thereof, and solvents generally used in this field can be used.

Examples of the solvent include glycol ether esters such as ethylcellosolve acetate, methylcellosolve acetate, propylene glycol monomethyl ether acetate and the like, ethers such as diethylene glycol dimethyl ether and the like, esters such as ethyl lactate, butyl acetate, amyl acetate, ethyl pyruvate and the like, ketones such as acetone, methyl isobutyl ketone, 2-heptanone, cyclohexanone and the like, cyclic esters such as γ-butyrolactone and the like. These solvents can be used alone or in combination of two or more.

A resist film applied on a substrate and dried is subjected to exposure treatment for patterning, then, to heating treatment for promoting a protective group-cleaving reaction, then, developed with alkali developer. As the alkali developer, various alkaline aqueous solutions usually used in this field can be used.

As the alkali developer, for example, aqueous solutions of tetramethylammonium hydroxide, (2-hydroxyethyl)trimethylammonium hydroxide (trivially, coline) and the like are preferably used.

Thus obtained resist film is excellent in resolution in exposure and transmission against lights having a wavelength of 170 nm or less, and particularly, suitable for F₂ excimer laser lithography.

### EXAMPLES

The present invention will be further illustrated based on examples, but it is needless to say that the scope of the present invention is not limited by the examples.

In the examples, “parts” are by weight unless otherwise stated.

The weight-average molecular weight is a value determined by gel permeation chromatography using polystyrene as a standard.

### Monomer Production Example 1

Into a 300 mL three-necked flask equipped with a magnetic stirrer, dry ice/acetone cooling tube, thermometer and nitrogen introducing tube was added 6.8 g of magnesium and 25 ml of tetrahydrofuran (THF), and a nitrogen atmosphere was made in the flask. 20 ml of THF into which 6.8 g of p-bromostyrene had been dissolved was added dropwise slowly while stirring this solution. Subsequently, 90 ml of THF into which 29.8 g of p-bromostyrene had been dissolved was added dropwise slowly so as to keep a reaction temperature of 35° C. After completion of addition, the mixture was refluxed for 1 hour, then, 66 g of a hexafluoroacetone gas was allowed to pass through the reaction solution slowly over 6 hours. After completion of the reaction, the mixture was poured into a large amount of ice water, and the resulted solid was washed with a 5% hydrochloric acid aqueous solution, extracted into a 5% sodium hydroxide aqueous solution, neutralized with a 5% hydrochloric acid aqueous solution, and dried, then, p-(1,1,1,3,3,3-hexafluoro-2-hydroxypropyl)styrene was obtained by distillation under reduced pressure. Yield: 35.2 g. This compound is called Monomer A.

### Monomer Production Example 2

Into a 100 mL three-necked flask equipped with a magnetic stirrer and a simple distillation apparatus was added 16.0 g of α-trifluoromethylacrylic acid and 34.8 g of phthalic chloride, the mixture was distilled while heating at from 130° C. to 150° C., and the extracted solution was diluted with 10 ml of dry THF. Into another 200 mL three-necked flask equipped with a magnetic stirrer, cooling tube and dropping funnel was charged 18.0 g of 2-ethyl-2-adamantanol, 100 mL of dry THF and 7.9 g of pyridine and the mixture was cooled to −40° C., and a THF solution of the extracted solution obtained in the prior reaction was added dropwise over 3 minutes. Then, the mixture was heated to 5° C. over 2 hours. There action solution was diluted with hexane, washed with water and concentrated, and 2-ethyladamantyl α-trifluoromethylacrylic acid was obtained by column purification. Yield: 9.5 g. This compound is called Monomer B.

### Resin Production Example 1

Into a 100 mL three-necked flask equipped with a magnetic stirrer, cooling tube, thermometer and nitrogen introducing tube was added 4.4 g of Monomer A, 0.5 g of styrene, 2.1 g of 2-methyl-2-adamantyl methacrylate and 7 g of 1,4-dioxane and the mixture was heated to 75° C., and a solution obtained by dissolving 0.2 g of azobisisobutyronitrile in 2 g of 1,4-dioxane was added drop wise over 30 minutes. Then, the mixture was heated for 8 hours while keeping the temperature at 75° C. Then, the reaction solution was poured into a mixed solution of 100 g of methanol and 350 g of water, the precipitated resin was separated by filtration and subjected to drying under reduced pressure to obtain a resin. Yield: 5.1 g. Weight-average molecular weight: 40000. This resin is called Resin 1.

### Resin Production Example 2

Into a 100 mL three-necked flask equipped with a magnetic stirrer, cooling tube, thermometer and nitrogen introducing tube was added 4.7 g of Monomer A, 1.8 g of 2-methyl-2-adamantyl methacrylate and 7 g of 1,4-dioxane and the mixture was heated to 75° C., and a solution obtained by dissolving 0.16 g of azobisisobutyronitrile in 2 g of 1,4-dioxane was added dropwise over 30 minutes. Then, the mixture was heated for 8 hours while keeping the temperature at 75° C. Then, the reaction solution was poured into a mixed solution of 100 g of methanol and 350 g of water, the precipitated resin was separated by filtration and subjected to drying under reduced pressure to obtain a resin. Yield: 5.1 g. Weight-average molecular weight: 20000. This resin is called Resin 2.

### Resin Production Example 3

Into a 100 mL three-necked flask equipped with a magnetic stirrer, cooling tube, thermometer and nitrogen introducing tube was added 5.4 g of Monomer A, 1.2 g of 2-methyl-2-adamantyl methacrylate and 7 g of 1,4-dioxane and the mixture was heated to 75° C., and a solution obtained by dissolving 0.16 g of azobisisobutyronitrile in 2 g of 1,4-dioxane was added dropwise over 30 minutes. Then, the mixture was heated for 8 hours while keeping the temperature at 75° C. Then, the reaction solution was poured into a mixed solution of 100 g of methanol and 350 g of water, the precipitated resin was separated by filtration and subjected to drying under reduced pressure to obtain a resin. Yield: 5.1 g. Weight-average molecular weight: 15000. This resin is called Resin 3.

### Resin Production Example 4

Into a 100 mL three-necked flask equipped with a magnetic stirrer, cooling tube, thermometer and nitrogen introducing tube was added 5.3 g of methyl isobutyl ketone and the mixture was heated to 75° C., and a solution obtained by mixing 3.4 g of Monomer A, 0.4 g of methacrylonitrile, 1.5 g of 2-methyl-2-adamantyl methacrylate, 0.25 g of azobisisobutyronitrile and 5.3 g of methyl isobutyl ketone was added dropwise over 30 minutes. Then, the mixture was heated for 8 hours while keeping the temperature at 75° C. Then, the reaction solution was poured into 500 mL of hexane, the precipitated resin was separated by filtration and subjected to drying under reduced pressure to obtain a resin. Yield: 3.8 g. Weight-average molecular weight: 6900. This resin is called Resin 4.

### Resin Production Example 5

Into a 100 mL three-necked flask equipped with a magnetic stirrer, cooling tube, thermometer and nitrogen introducing tube was added 6.4 g of methyl isobutyl ketone and the mixture was heated to 75° C., and a solution obtained by mixing 4.1 g of Monomer A, 0.5 g of methacrylonitrile, 1.9 g of 2-ethyl-2-adamantyl methacrylate, 0.30 g of azobisisobutyronitrile and 6.4 g of methyl isobutyl ketone was added dropwise over 30 minutes. Then, the mixture was heated for 8 hours while keeping the temperature at 75° C. Then, the reaction solution was poured into 500 mL of hexane, the precipitated resin was separated by filtration and subjected to drying under reduced pressure to obtain a resin. Yield: 4.9 g. Weight-average molecular weight: 9400. This resin is called Resin 5.

### Resin Production Example 6

Into a 100 mL three-necked flask equipped with a magnetic stirrer, cooling tube, thermometer and nitrogen introducing tube was added 5.3 g of 2-propanol and the mixture was heated to 75° C., and a solution obtained by mixing 6.5 g of Monomer A, 1.5 g of 2-ethyl-2-adamantyl methacrylate, 0.12 g of azobisisobutyronitrile and 2.7 g of 2-propanol was added dropwise over 30 minutes. Then, the mixture was heated for 8 hours while keeping the temperature at 75° C. Then, the reaction solution was poured into 500 mL of water, the precipitated resin was separated by filtration and subjected to drying under reduced pressure to obtain a resin. Yield: 7.7 g. Weight-average molecular weight: 26400. This resin is called Resin 6.

### Resin Production Example 7

Into a 100 mL three-necked flask equipped with a magnetic stirrer, cooling tube, thermometer and nitrogen introducing tube was added 8.0 g of methyl isobutyl ketone and the mixture was heated to 75° C., and a solution obtained by mixing 5.7 g of Monomer A, 2.3 g of 2-ethyl-2-adamantyl methacrylate, 0.3 g of azobisisobutyronitrile and 8.0 g of methyl isobutyl ketone was added dropwise over 30 minutes. Then, the mixture was heated for 8 hours while keeping the temperature at 75° C. Then, the reaction solution was poured into 500 mL of water, the precipitated resin was separated by filtration and subjected to drying under reduced pressure to obtain a resin. Yield: 7.0 g. Weight-average molecular weight: 8800. This resin is called Resin 7.

### Resin Production Example 8

Into a 100 mL three-necked flask equipped with a magnetic stirrer, cooling tube, thermometer and nitrogen introducing tube was added 7.8 g of methyl isobutyl ketone and the mixture was heated to 75° C., and a solution obtained by mixing 5.0 g of Monomer A, 2.2 g of Monomer B, 0.4 g of azobisisobutyronitrile and 7.8 g of methyl isobutyl ketone was added dropwise over 30 minutes. Then, the mixture was heated for 8 hours while keeping the temperature at 75° C. Then, the reaction solution was poured into 500 mL of water, the precipitated resin was separated by filtration and subjected to drying under reduced pressure to obtain a resin. Yield: 6.0 g. Weight-average molecular weight: 7000. This resin is called Resin 8.

Production of Resin X

(1) Into a flask was charged 24.6 g (0.105 mol) of 2-adamantyl-2-methyl methacrylate, 39.7 g (0.245 mol) of p-acetoxystyrene and 128.6 g of isopropanol and the atmosphere was purged with nitrogen, and the mixture was heated up to 75° C. To this solutionwas added dropwise 4.84 g (0.021 mol) of dimethyl 2,2-azobis(2-methylpropionate) dissolved in 9.7 g of isopropanol. The mixture was aged for about 0.5 hours at 75° C. and for about 11 hours under reflux, then, diluted with acetone, and charged into heptane to cause crystallization, the crystal was removed by filtration, and the resulted crystal was dried. The resulted crystal of the copolymer of 2-adamantyl-2-methyl methacrylate and p-acetoxystyrene revealed a weight of 54.1 g.

(2) Into a flask was charged 53.2 g (0.29 mol in terms of monomer units) of the copolymer of 2-adamantyl-2-methyl methacrylate and p-acetoxystyrene (30:70) obtained above, 5.3 g (0.043 mol) of 4-dimethylaminopyridine and 59.5 g of methanol, and the mixture was aged for 20 hours under reflux. After cooling, the mixture was neutralized with 3.92 g (0.065 mol) of glacial acetic acid, charged in water to cause crystallization, and the crystal was removed by filtration. Then, the crystal was dissolved in acetone, charged in water to cause crystallization, and the crystal was removed by filtration. This series of operation was repeated three times, then, the resulted crystal was dried. The resulted crystal of the copolymer of 2-adamantyl-2-methyl methacrylate and p-hydroxystyrene revealed a weight of 41.2 g. The weight-average molecular weight was about 8100, the degree of dispersion was 1.68 (GPC method; in terms of polystyrene), and the copolymerization ratio was measured as about 30:70 by a nuclear magnetic resonance (¹³C-NMR) spectrometer. This resin is called Resin X.

### Production of Resin Y

(1) Into a flask was charged 16.4 g (0.07 mol) of 2-adamantyl-2-methyl methacrylate, 45.4 g (0.28 mol) of p-acetoxystyrene and 123.6 g of isopropanol and the atmosphere was purged with nitrogen, and the mixture was heated up to 75° C. To this solutionwas added dropwise 4.84 g (0.021 mol) of dimethyl 2,2-azobis(2-methylpropionate) dissolved in 9.7 g of isopropanol. The mixture was aged for about 0.5 hours at 75° C. and for about 11 hours under reflux, then, diluted with acetone, and charged into heptane to cause crystallization, the crystal was removed by filtration, and the resulted crystal was dried. The resulted crystal of the copolymer of 2-adamantyl-2-methyl methacrylate and p-acetoxystyrene revealed a weight of 54.2 g.

(2) Into a flask was charged 53.0 g (0.30 mol in terms of monomer units) of the copolymer of 2-adamantyl-2-methyl methacrylate and p-acetoxystyrene (20:80) obtained above, 5.3 g (0.043 mol) of 4-dimethylaminopyridine and 159.0 g of methanol, and the mixture was aged for 20 hours under reflux. After cooling, the mixture was neutralized with 3.13 g (0.052 mol) of glacial acetic acid, charged in water to cause crystallization, and the crystal was removed by filtration. Then, the crystal was dissolved in acetone, charged in water to cause crystallization, and the crystal was removed by filtration. This series of operation was repeated three times, then, the resulted crystal was dried. The resulted crystal of the copolymer of 2-adamantyl-2-methyl methacrylate and p-hydroxystyrene revealed a weight of 37.8 g. The weight-average molecular weight was about 7900, the degree of dispersion was 1.72 (GPC method; in terms of polystyrene), and the copolymerization ratio was measured as about 20:80 by a nuclear magnetic resonance (¹³C-NMR) spectrometer. This resin is called Resin Y.

Next, resist compositions were prepared using an acid generator and a quencher shown below, in addition to the resins obtained in the above-described resin production examples.

<Acid Generator>

### B1: bis(4-t-butylphenyliodonium Camphorsulfonate)

<Quencher>

### C1: 2,6-diisopropylaniline

### Examples 1 to 7 and Comparative Examples 1 to 3

The following components were mixed and dissolved, further, filtrated through a fluorine resin filter having a pore diameter of 0.2 μm, to prepare a resist solution.

| Resin (kind is described in Table 1) | 10 | parts by weight |
|---|---|---|
| Acid generator (B1) | 0.52 | parts by weight |
| Quencher (C1) | (amount is described | |
| | in Table 1) | |
| Solvent: methyl amyl ketone | 50 | parts by weight |

Measurement of Transmission

On the other hand, the resist solution prepared above was applied on a magnesium fluoride wafer to give a film thickness after drying of 0.1 μm, and pre-baked on a direct hot plate under conditions of 130° C. and 60 seconds, to form a resist film. The transmission of thus formed resist film at a wavelength of 157 nm was measured by using a vacuum ultraviolet spectrophotometer (manufactured by Nippon Bunko K. K.) to obtain results shown in Table 1.

Measurement of KrF Exposure and Film Permeating Sensitivity

“DUV-42”, an organic anti-reflective coating composition manufactured by Brewer was applied on a silicon wafer and baked under conditions of 215° C. and 60 seconds to form an organic anti-reflective coating having a thickness of 600 Å, and the resist solution prepared above was spin-coated on the silicon wafer so that the film thickness after drying was 0.523 μm. After application of the resist solution, the solution was pre-baked (PB) for 60 seconds at temperature shown in Table 1 on a direct hot plate. The wafer carrying thus formed resist film was exposed through a line and space pattern while changing the exposure amount gradually using a KeF excimer stepper [“NSR2205 EX-12B”, manufactured by Nikon Corp., NA=0.55, τ=0.8].

After exposure, the wafer was subjected to post exposure bake (PEB) for 60 seconds at temperature shown in Table 1 on a hot plate, and further, subjected to paddle development of 60 seconds with a 2.38 wt % tetramethylammonium hydroxide aqueous solution. The wafer after development was visually observed, and the minimum exposure amount manifesting film permeation of the resist (film permeation sensitivity) was measured, to obtain results shown in Table 1.

Measurement of F₂ Exposure, Film Permeation Sensitivity and γ Value

On a silicon wafer which had been treated for 20 seconds at 23° C. with hexamethylsilazane, the resist solution prepared above was applied so that the film thickness after drying was 0.1 μm. Pre-bake of 60 seconds at temperature shown in Table 1 was conducted on a direct hot plate. The wafer carrying thus formed resist film was exposed in open frame mode while changing the exposure amount gradually using a F₂ excimer laser exposing apparatus [“VUVES-4500”, available from LithoTech Japan]. After exposure, the wafer was subjected to post exposure bake (PEB) for 60 seconds at temperature shown in Table 1 on a direct hot plate, and further, subjected to paddle development of 60 seconds with a 2.38 wt % tetramethylammonium hydroxide aqueous solution. The wafer after development was visually observed, and the minimum exposure amount manifesting film permeation of the resist (film permeation sensitivity) was measured. The results are shown in Table 1.

Further, the remaining film thickness against the exposure amount was measured by Random Ace film thickness measuring apparatus (manufactured by Dainippon Screen Mfg Co., Ltd.), and values were plotted logarithm of exposure amount in the abscissa and normalized film thickness after PEB in the ordinate. The inclination of inclined part (tan θ) of the resulted sensitivity curve was γ-value. The γ-value is an index of resolution, and when it is larger, contrast between non-exposed parts and exposed parts is higher and resolution is more excellent.

TABLE 1

| | | | Trans- | | Film | F2 exposure | |
|---|---|---|---|---|---|---|---|
| | | C1 | mission | | permeation | Film | |
| | | parts | at | PB/PEB | sensitivity in | permeation | |
| | | by | 157 nm | temperature | KrF exposure | sensitivity | γ |
| | Resin | weight | (%) | (° C.) | (mJ/cm²) | (mJ/cm²) | -value |
| Example | Resin | 0.052 | 34 | 130/140 | 24 | 4 | 7.0 |
| 1 | 1 | | | | | | |
| Example | Resin | 0.052 | 37 | 130/140 | 20 | 3 | 5.3 |
| 2 | 2 | | | | | | |
| Example | Resin | 0.052 | 40 | 130/140 | 16 | 2 | 2.0 |
| 3 | 3 | | | | | | |
| Example | Resin | 0.01 | 39 | 110/120 | 45 | 4.5 | 3.0 |
| 4 | 4 | | | | | | |
| Example | Resin | 0.01 | 39 | 110/120 | 15 | 2 | 8.0 |
| 5 | 5 | | | | | | |
| Example | Resin | 0.052 | 41 | 130/80 | 75 | 5 | 1.2 |
| 6 | 6 | | | | | | |
| Example | Resin | 0.052 | 39 | 130/80 | 75 | 8 | 2.3 |
| 7 | 7 | | | | | | |
| Example | Resin | 0.01 | 44 | 110/120 | | | |
| 8 | 8 | | | ⅓ dilution | 42 | 7 | 3.0 |
| | | | | and | | | |
| | | | | development | | | |
| | | | | ¼ dilution | 56 | 8 | 4.4 |
| | | | | and | | | |
| | | | | development | | | |
| Compara- | Resin | 0.052 | 20 | 130/140 | 26 | 4 | 1.7 |
| tive | X | | | | | | |
| example | | | | | | | |
| 1 | | | | | | | |
| Compara- | Resin | 0.01 | 21 | 130/140 | 12 | 1.5 | 2.0 |
| tive | X/Y = 1 | | | | | | |
| example | | | | | | | |
| 2 | | | | | | | |
| Compara- | Resin | 0.052 | 23 | 130/140 | 20 | 3 | 1.3 |
| tive | Y | | | | | | |
| example | | | | | | | |
| 3 | | | | | | | |

According to the present invention, a positive resist composition excellent in resolution in exposure and transmission against light having a wavelength of 170 nm or less, for example, F₂ excimer laser having a wavelength of 157 nm, can be provided.

What is claimed is:

1. A positive resist composition comprising a binder resin and a radiation-sensitive compound, wherein the binder resin contains a polymerization unit of the following formula (I) and a polymerization unit of the following formula (II) and becomes alkali-soluble by the radiation-sensitive compound after irradiation with radioactive ray: 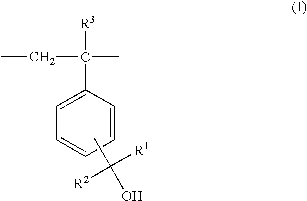
wherein, R¹ and R² each independently represent a fluoroalkyl group having 1 to 12 carbon atoms and carrying at least one fluorine atom, and R³ represents a hydrogen atom, halogen atom, cyano group, alkyl group having 1 to 3 carbon atoms or a fluoroalkyl group having 1 to 3 carbon atoms and carrying at least one fluorine atom, 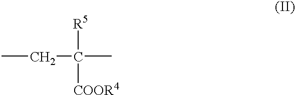
wherein, R⁴ represents a group which is cleaved by an acid, and R⁵ represents a hydrogen atom, halogen atom, cyano group, alkyl group having 1 to 3 carbon atoms or a fluoroalkyl group having 1 to 3 carbon atoms and carrying at least one fluorine atom.

2. The composition according to claim 1, wherein the binder resin contains 5 to 95 mol % of a polymerization unit of the formula (I) and 95 to 5 mol % of a polymerization unit of the formula (II).

3. The composition according to claim 1, wherein the polymerization unit of the formula (I) is a polymerization unit of the following formula (III): 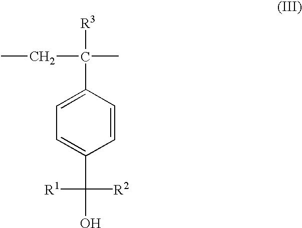
wherein R¹, R² and R³ are as defined above.

4. The composition according to claim 3, wherein the binder resin contains 5 to 95 mol % of a polymerization unit of the formula (III) and 95 to 5 mol % of a polymerization unit of the formula (II).

5. The composition according to claim 1, wherein R¹ and R² represents a trifluoromethyl group.

6. The composition according to claim 1, wherein the radiation-sensitive compound is an active compound which generate an acid by the radioactive ray and acts in positive mode.

7. The composition according to claim 1, wherein R⁴ is a 2-alkyl-2-adamantyl group.

8. The composition according to claim 1, wherein the binder resin further contains a polymerization unit of the following formula (IV): 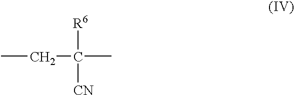
wherein, R⁶ represents a hydrogen atom, halogen atom, cyano group, alkyl group having 1 to 3 carbon atoms or a fluoroalkyl group having 1 to 3 carbon atoms and carrying at least one fluorine atom.

9. The composition according to claim 1, wherein the binder resin further contains a polymerization unit of the following formula (V): 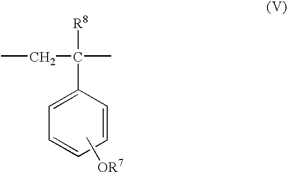
wherein, R⁷ represents a group which is cleaved by the action of an acid, or a hydrogen atom, and R⁸ represents a hydrogen atom, halogen atom, cyano group, alkyl group having 1 to 3 carbon atoms or a fluoroalkyl group having 1 to 3 carbon atoms and carrying at least one fluorine atom.
